(19) United States
(12) Patent Application Publication
(10) Pub. No.: US 2025/0218804 A1
(43) Pub. Date: Jul. 3, 2025

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventor: Makoto HIRANO, Toyama-shi (JP)

(73) Assignee: Kokusai Electric Corporation, Tokyo (JP)

(21) Appl. No.: 19/084,116

(22) Filed: Mar. 19, 2025

Related U.S. Application Data
(63) Continuation of application No. PCT/JP2022/035231, filed on Sep. 21, 2022.

(51) Int. Cl. H01L 21/67

(52) U.S. Cl. CPC H01L 21/67017

(57) ABSTRACT

Included is a process chamber configured to process a substrate; at least one vaporizer that vaporizes a source supplied as a liquid to generate a source gas; at least two tanks that accumulates the source gas extracted from the vaporizer; pipe coupling the at least two tanks to each other; a first valve provided in the pipe; and a gas supplier that supplies the source gas into the process chamber from the at least two tanks.

### CROSS-REFERENCE TO RELATED APPLICATION

This application is a Bypass Continuation Application of PCT International Application No. PCT/JP2022/035231, filed on Sep. 21, 2022, the entire contents of which are incorporated herein by reference.

### BACKGROUND

### Field

The present disclosure relates to a substrate processing apparatus, a method of processing a substrate, a method of manufacturing a semiconductor device, and a recording medium.

### Description of the Related Art

As one aspect of a substrate processing apparatus used in a step of manufacturing a semiconductor device, for example, a substrate processing apparatus is used that collectively processes a plurality of substrates.

### SUMMARY

The present disclosure provides a technique that makes it possible to uniformly perform processing on a plurality of substrates.

According to one aspect of the present disclosure,
there is provided a technique including:
a process chamber configured to process a substrate;
at least one vaporizer that vaporizes a source supplied as a liquid to generate a source gas;
at least two tanks that accumulates the source gas extracted from the vaporizer;
pipe coupling the at least two tanks to each other;
a first valve provided in the pipe; and
a gas supplier that supplies the source gas into the process chamber from the at least two tanks.

### BRIEF DESCRIPTION OF THE DRAWINGS

FIG. 1 is an explanatory diagram illustrating a schematic configuration example of substrate processing a apparatus according to one aspect of the present disclosure.

FIG. 2 is an explanatory diagram illustrating a schematic configuration example of the substrate processing apparatus according to one aspect of the present disclosure.

FIG. 3 is an explanatory diagram illustrating a schematic configuration example of the substrate processing apparatus according to one aspect of the present disclosure.

FIG. 4 is an explanatory diagram explaining a substrate support according to one aspect of the present disclosure.

FIG. 5 is an explanatory diagram illustrating an example of a first gas supply system according to one aspect of the present disclosure.

FIG. 6 is an explanatory diagram illustrating a second gas supply system according to one aspect of the present disclosure.

FIG. 7 is an explanatory diagram explaining a gas exhaust system according to one aspect of the present disclosure.

FIG. 8 is an explanatory diagram explaining a controller of the substrate processing apparatus according to one aspect of the present disclosure.

FIG. 9 is a flow diagram explaining a substrate processing flow according to one aspect of the present disclosure.

FIG. 10 is a chart diagram explaining control processing at the time of gas supply according to one aspect of the present disclosure.

FIG. 11 is an explanatory diagram illustrating another example of the first gas supply system according to one aspect of the present disclosure.

FIGS. 12A and 12B are explanatory diagrams illustrating still another example of the first gas supply system according to one aspect of the present disclosure, in which FIG. 12A is a diagram illustrating an overall schematic configuration, and FIG. 12B is a diagram of a substrate periphery viewed from above.

### DETAILED DESCRIPTION

Hereinafter, embodiments of the present aspect will be described with reference to the drawings. The drawings used in the following descriptions are all schematic, and dimensional relationships of elements, ratios of the elements, and the like in the drawings do not necessarily coincide with actual ones. In addition, for example, a plurality of drawings does not necessarily coincide with each other in the dimensional relationship between each element or in the ratio between each element.

### (1) Configuration of Substrate Processing Apparatus

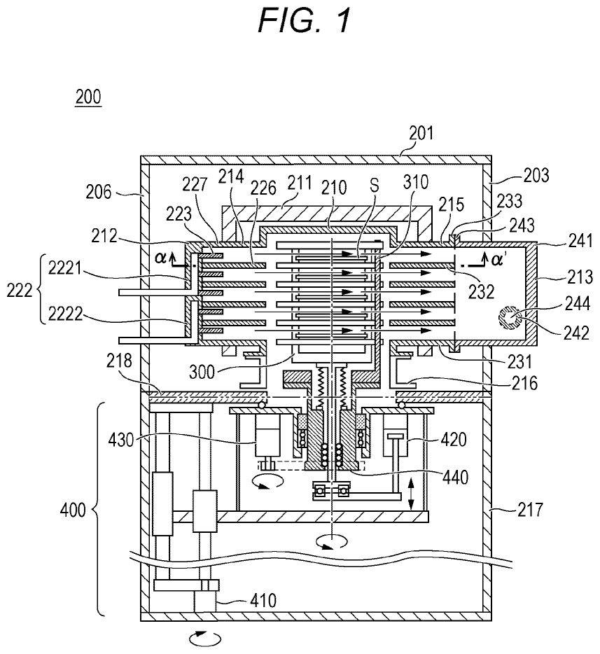

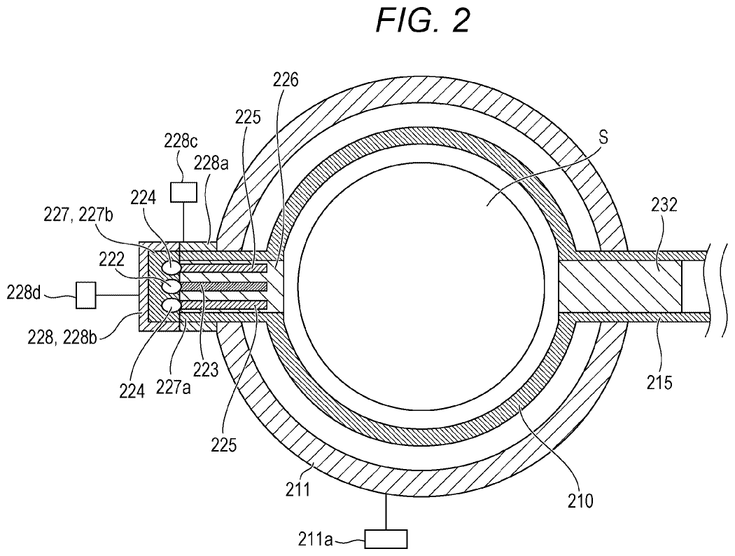

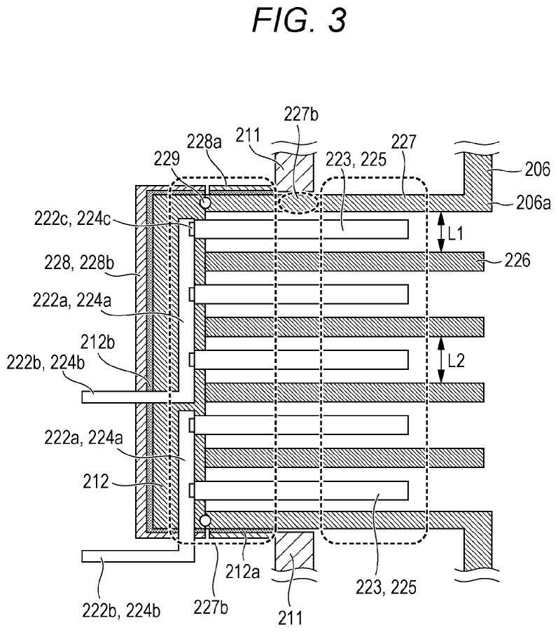

A schematic configuration of a substrate processing apparatus according to one aspect of the present disclosure will be described with reference to FIGS. 1 to 3. FIG. 1 is a side sectional view of a substrate processing apparatus 100, and FIG. 2 is a sectional view taken along a line α-α′ in FIG. 1. For convenience of explanation, a nozzle 223 and a nozzle 225 are added here. FIG. 3 is an explanatory diagram explaining a relationship between a housing 227, a heater 211, and a distributor. For convenience of explanation, a distributor 222 and the nozzle 223 are illustrated, and a distributor 224 and the nozzle 225 are omitted here.

### Overall Configuration

Next, specific details will be described. The substrate processing apparatus 100 includes a housing 201, and the housing 201 includes a reaction tube storage chamber 206 and a transfer chamber 217. The reaction tube storage chamber 206 is disposed above the transfer chamber 217.

The reaction tube storage chamber 206 includes a reaction tube 210 in a cylindrical shape extending in the vertical direction, the heater 211 serving as a heater (furnace body) installed on the outer periphery of the reaction tube 210, a gas supply structure 212 serving as a gas supplier, and a gas exhaust structure 213 serving as a gas exhauster. Here, the reaction tube 210 is also referred to as a process chamber, and a space inside the reaction tube 210 is also referred to as a processing space. The reaction tube 210 can store a substrate support tool 300 to be described later.

In the heater 211, a resistance heater is provided on an inner surface facing the side of the reaction tube 210, and a heat insulator is provided to surround the resistance heater. Thus, the outer side of the heater 211, that is, the side not facing the reaction tube 210 is configured to have less thermal influence. A heater controller 211a is electrically coupled to the resistance heater of the heater 211. With the heater controller 211a controlled, on/off of the heater 211 and a heating temperature can be controlled. The heater 211 is capable of heating a gas to be described later to a temperature at which the gas can be thermally decomposed. The heater 211 is also referred to as a process chamber heater or a first heater.

The reaction tube 210, an upstream side gas guide 214, and a downstream side gas guide 215 are provided inside the reaction tube storage chamber 206. The gas supplier may include the upstream side gas guide 214. In addition, the gas exhauster may include the downstream side gas guide 215.

The gas supply structure 212 is provided upstream in the gas flow direction of the reaction tube 210, and the gas is supplied from the gas supply structure 212 to the reaction tube 210. The gas exhaust structure 213 is provided downstream in the gas flow direction of the reaction tube 210, and the gas inside the reaction tube 210 is discharged from the gas exhaust structure 213.

The upstream side gas guide 214 that guides the flow of the gas supplied from the gas supply structure 212 is provided between the reaction tube 210 and the gas supply structure 212. That is, the gas supply structure 212 is adjacent to the upstream side gas guide 214. The downstream side gas guide 215 that guides the flow of the gas discharged from the reaction tube 210 is provided between the reaction tube 210 and the gas exhaust structure 213. The reaction tube 210 has a lower end supported by a manifold 216.

The reaction tube 210, the upstream side gas guide 214, and the downstream side gas guide 215 are provided as a continuous structure, and are formed of a material such as quartz or SiC, for example. These include a heat-permeable member that allows heat radiated from the heater 211 to pass through. The heat from the heater 211 causes a substrate S and the gas to be heated.

A housing constituting the gas supply structure 212 includes metal, and the housing 227, which is a part of the upstream side gas guide 214, includes quartz or the like. The gas supply structure 212 and the housing 227 are separable from each other, and are fixed with an O-ring 229 interposed therebetween when being fixed. The housing 227 is coupled to a connection portion 206a on the lateral side of the reaction tube 210.

The housing 227 extends in a direction different from the reaction tube 210 when viewed from the side of the reaction tube 210, and is coupled to the gas supply structure 212 to be described later. The heater 211 and the housing 227 are adjacent to each other at an adjacent portion 227b between the reaction tube 210 and the gas supply structure 212. The adjacent portions are referred to as the adjacent portion 227b.

### Gas Supply Structure

The gas supply structure 212 is provided on the rear side of the adjacent portion 227b when viewed from the reaction tube 210. The gas supply structure 212 includes a distributor 224 communicable with a gas supply pipe 261 and a distributor 222 communicable with a gas supply pipe 251, which will be described later. A plurality of the nozzles 223 is provided on the downstream side of the distributor 222, and a plurality of the nozzles 225 is provided downstream of the distributor 224. The plurality of nozzles is disposed in the vertical direction. The distributor 222 and the nozzles 223 are illustrated in FIG. 1.

As will be described later, since the distributor 222 enables distribution of a source gas, it is also referred to as a source gas distributor. Since the nozzles 223 supply the source gas, they are also referred to as source gas supply nozzles.

In addition, since the distributor 224 enables distribution of a reactant gas, it is also referred to as a reactant gas distributor. Since the nozzles 225 supply the reactant gas, they are also referred to as reactant gas supply nozzles.

As illustrated in FIG. 1, the distributor 222 is divided into at least two portions (in the drawing, a case is illustrated where only there are two portions). Specifically, the distributor 222 includes a first distributor 2221 and a second distributor 2222. The first distributor 2221 and the second distributor 2222 are for supplying a source gas to different regions in the substrate support tool 300 described later. Note that the first distributor 2221 and the second distributor 2222 may be configured in the same manner, or may have different configurations (for example, may be different in the number of nozzles 223 on the downstream side) as in the illustrated example.

Unlike the distributor 222, the distributor 224 includes one portion without being divided. However, similarly to the distributor 222, the distributor 224 may be divided into at least two portions.

The gas supply pipe 251 communicating with the distributor 222 and the gas supply pipe 261 communicating with the distributor 224 supply different types of gases as described later. As illustrated in FIG. 2, the nozzles 223 provided downstream of the distributor 222 and the nozzles 225 provided downstream of the distributor 224 are disposed in a side-by-side relationship. Here, in the horizontal direction, the nozzle 223 is disposed at the center of the housing 227, and the nozzles 225 are disposed on both sides thereof. The nozzles disposed on both sides will be referred to as nozzles 225a and 225b, respectively.

As illustrated in FIG. 3, the distributor 222 (that is, each of the first distributor 2221 and the second distributor 2222) is provided with a plurality of blow-off holes 222c. The blow-off holes 222c are provided not to overlap each other in the vertical direction. The plurality of nozzles 223 is coupled to the blow-off holes 222c provided in the distributor 222 such that the blow-off holes 222c communicates with the inside of the respective nozzles 223. The nozzles 223 are disposed in the vertical direction between division plates 226 to be described later or between the housing 227 and the division plate 226.

The distributor 222 (that is, each of the first distributor 2221 and the second distributor 2222) includes a distribution structure 222a coupled to the nozzle 223 and an introduction pipe 222b. The introduction pipe 222b communicates with the gas supply pipe 251 of a gas supplier 250 to be described later.

The distribution structure 222a is disposed on the rear side of the heater 211 when viewed from the reaction tube 210. Thus, the distribution structure 222a is disposed at a position not easily affected by the heater 211.

An upstream side heater 228 capable of heating at a temperature lower than that of the heater 211 is provided around the gas supply structure 212 and the housing 227. The upstream side heater 228 includes two heaters 228a and 228b. Specifically, the upstream side heater 228a is provided around a surface that is a surface of the housing 227 and a surface between the gas supply structure 212 and the adjacent portion 227b. In addition, the upstream side heater 228b is provided around the gas supply structure 212. The upstream side heater 228 is also referred to as an upstream side heater or a second heater.

Here, a low temperature indicates a temperature at which the gas supplied into the distributor 222 is not re-liquefied, for example, and is also a temperature at which a low decomposition state of the gas is maintained.

Similarly to the distributor 222, the distributor 224 includes a distribution structure 224a coupled to the nozzles 225, and an introduction pipe 224b. The introduction pipe 224b communicates with the gas supply pipe 261 of a gas supplier 260 to be described later. The distributor 224 and the plurality of nozzles 225 are coupled to each other such that holes 224c provided in the distributor 224 communicate with the inside of the respective nozzles 225. As illustrated in FIG. 2, a plurality of, for example, two distributors 224 and nozzles 225 are provided, and the gas supply pipe 261 communicates with each of them. The plurality of nozzles 225 is disposed at line-symmetric positions around the nozzle 223, for example.

As described above, with the distributor and the nozzles provided for each gas to be supplied, the gas supplied from each of the gas supply pipes is not mixed in each of the gas distributors, whereby generation of particles, which can be generated by gases being mixed in the distributor 224, can be suppressed.

At least a part of the configuration of the upstream side heater 228a is disposed in parallel with the extending direction of the nozzle 223 and the nozzle 225. At least a part of the configuration of the upstream side heater 228b is provided along the arrangement direction of the distributor 222. With this arrangement, the low temperature can be maintained even in the nozzles and in the distributors.

Heater controllers 228c and 228d are electrically coupled to the upstream side heater 228. Specifically, the heater controller 228c is coupled to the upstream side heater 228a, and the heater controller 228d is coupled to the upstream side heater 228b. With the heater controllers 228c and 228d controlled, on/off of the heater 228 and a heating temperature can be controlled. Although the two heater controllers 228c and 228d have been described here, it is not limited thereto, and one heater controller or three or more heater controllers may be used as long as desired temperature control is enabled. The upstream side heater 228 is also referred to as a second heater.

The upstream side heater 228 is detachable, and can be detached in advance from the gas supply structure 212 and the housing 227 at the time of separating the gas supply structure 212 and the housing 227 from each other. In addition, it may be fixed to each part, and at the time of separating the gas supply structure 212 and the housing 227 from each other, the gas supply structure 212 and the housing 227 may be separated from each other while it is fixed to the gas supply structure 212 or the housing 227.

A metal cover 212a made of, for example, metal, which serves as a cover, may be provided between the upstream side heater 228a and the housing 227. With the metal cover 212a provided, heat generated by the upstream side heater 228a can be efficiently supplied into the housing 227. In particular, while there is concern about heat dissipation in the housing 227 due to its material of quartz, the heat dissipation can be suppressed by the metal cover 212a being provided. Accordingly, it is not needed to perform excessive heating, whereby power supply to the heater 228 can be reduced.

A metal cover 212b may be provided between the upstream side heater 228b and the housing constituting the gas supply structure 212. With the metal cover 212b provided, heat generated by the upstream side heater 228b can be efficiently supplied to the distributor. Accordingly, the power supply to the upstream side heater 228 can be reduced.

### Upstream Side Gas Guide

The upstream side gas guide 214 includes the housing 227 and the division plates 226. A part of the division plate 226 serving as a partition facing the substrate S is extended in the horizontal direction to be larger than at least the diameter of the substrate S. The horizontal direction mentioned here indicates a side wall direction of the housing 227. A plurality of the division plates 226 is disposed in the vertical direction in the housing 227. The division plate 226 is fixed to the side wall of the housing 227, and is configured such that the gas does not move to a lower or upper adjacent region beyond the division plate 226. With such a configuration in which the gas does not move beyond, a gas flow to be described later can be reliably formed.

The division plates 226 have a continuous structure without a hole. Each of the division plates 226 is provided at a position corresponding to the substrate S. The nozzle 223 and the nozzle 225 are provided between the division plates 226 and between the division plate 226 and the housing 227. That is, the nozzle 223 and the nozzle 225 are provided at least for each division plate 226. With such a configuration, it becomes possible to execute a process using a first gas and a second gas for each of the spaces between the division plates 226 and between the division plate 226 and the housing 227. Thus, processing can be uniformed between a plurality of the substrates S.

The respective distances between the division plates 226 and the nozzles 223 disposed above the division plates 226 are desirably the same. That is, arrangement is made in which the respective spaces have the same heights between the nozzle 223 and the division plate 226 or the housing 227 disposed below the nozzle 223. With this arrangement, the distance from the tip of the nozzle 223 to the division plate 226 can be made the same, whereby a degree of decomposition on the substrate S can be uniformed among the plurality of substrates.

The gas flow of the gas discharged from the nozzle 223 and the nozzle 225 is guided by the division plate 226, and is supplied to the surface of the substrate S. Since the division plate 226 extends in the horizontal direction and has a continuous structure without a hole, the mainstream of the gas is suppressed to move in the vertical direction, and moves in the horizontal direction. Thus, the pressure loss of the gas reaching each substrate S can be uniformed in the vertical direction.

In the present aspect, the diameter of the blow-off hole 222c provided in the distributor 222 is smaller than the distance between the division plates 226 or the distance between the housing 227 and the division plate 226.

### Downstream Side Gas Guide

The downstream side gas guide 215 is configured such that, in a state where the substrates S are supported by the substrate support tool 300, the ceiling is higher than the substrate S disposed at the uppermost position and the bottom is lower than the substrate S disposed at the lowermost position of the substrate support tool 300.

The downstream side gas guide 215 includes a housing 231 and a division plate 232. A portion of the division plate 232 facing the substrate S is extended in the horizontal direction to be larger than at least the diameter of the substrate S. The horizontal direction mentioned here indicates a side wall direction of the housing 231. Furthermore, a plurality of the division plates 232 is disposed in the vertical direction. The division plate 232 is fixed to the side wall of the housing 231, and is configured such that the gas does not move to a lower or upper adjacent region beyond the division plate 232. With such a configuration in which the gas does not move beyond, a gas flow to be described later can be reliably formed. A flange 233 is provided on the side of the housing 231 in contact with the gas exhaust structure 213.

The division plates 232 have a continuous structure without a hole. Each of the division plates 232 is provided at a position corresponding to the substrate S, the position corresponding to the division plate 226. The division plate 226 and the division plate 232 corresponding to each other are desirably equivalent in height. Furthermore, the height of the substrate S and the heights of the division plate 226 and the division plate 232 are desirably aligned at the time of processing the substrate S. With such a structure, the gas supplied from each nozzle forms a flow passing on the division plate 226, the substrate S, and the division plate 232 as indicated by the arrow in the drawing. At this time, the division plate 232 extends in the horizontal direction and has a continuous structure without a hole. With such a structure, the pressure loss of the gas discharged from each substrate S can be uniformed. Thus, the gas flow of the gas passing through each substrate S is formed in the horizontal direction toward the gas exhaust structure 213 while the flow in the vertical direction is suppressed.

With the division plate 226 and the division plate 232 provided, the pressure loss in the vertical direction can be uniformed on the upstream side and the downstream side of each substrate S, whereby the horizontal gas flow in which the flow in the vertical direction is suppressed can be reliably formed over the division plate 226, the substrate S, and the division plate 232.

### Gas Exhaust Structure

The gas exhaust structure 213 is provided downstream of the downstream side gas guide 215. The gas exhaust structure 213 mainly includes a housing 241 and a gas exhaust pipe connector 242. A flange 243 is provided on the side of the downstream side gas guide 215 of the housing 241.

The gas exhaust structure 213 communicates with a space of the downstream side gas guide 215. The housing 231 and the housing 241 have a structure continuous in height. The ceiling of the housing 231 has a height equivalent to that of the ceiling of the housing 241, and the bottom of the housing 231 has a height equivalent to that of the bottom of the housing 241.

The gas having passed through the downstream side gas guide 215 is exhausted from an exhaust hole 244. At this time, since the gas exhaust structure does not include a configuration like a division plate, a gas flow including the vertical direction is formed toward the gas exhaust hole.

The transfer chamber 217 is disposed below the reaction tube 210 with the manifold 216 interposed therebetween. In the transfer chamber 217, a vacuum transfer robot (not illustrated) places (mounts) the substrate S on the substrate support tool (which may be simply referred to as a boat hereinafter) 300, or the vacuum transfer robot takes out the substrate S from the substrate support tool 300.

The transfer chamber 217 can store therein the substrate support tool 300, a partition plate support 310, and an up-down direction drive mechanism 400 constituting a first driver that drives the substrate support tool 300 and the partition plate support 310 (which are collectively referred to as a substrate holder) in the up-down direction and in the rotational direction. FIG. 1 illustrates a state in which the substrate support tool 300 is raised by the up-down direction drive mechanism 400 and is stored in the reaction tube.

### Substrate Support

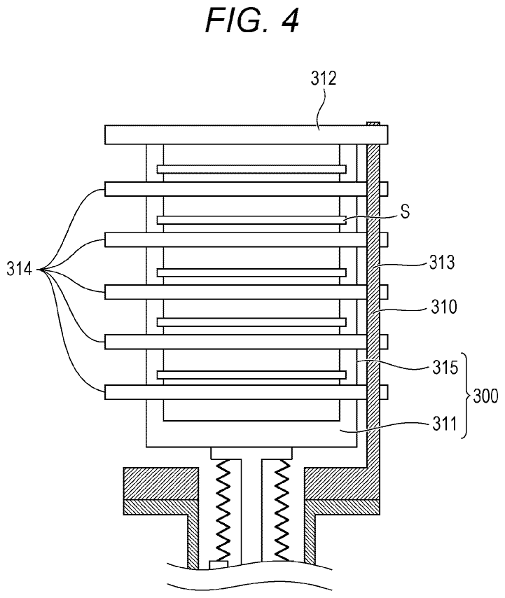

Next, details of a substrate support will be described with reference to FIGS. 1 and 4.

FIG. 4 is an explanatory diagram explaining the substrate support.

The substrate support includes at least the substrate support tool 300, and replaces, using the vacuum transfer robot, the substrate S via a substrate loading port 149 inside the transfer chamber 217, and transfers the replaced substrate S to the inside of the reaction tube 210 to form a thin film on the surface of the substrate S. The substrate support may include the partition plate support 310.

In the partition plate support 310, a plurality of partition plates 314 having a disk shape is fixed at a predetermined pitch to a column 313 supported between a base 311 and a top plate 312. The substrate support tool 300 is configured such that a plurality of support rods 315 is supported by the base 311, and the plurality of substrates S is supported by the plurality of support rods 315 at predetermined intervals.

The plurality of substrates S is placed on the substrate support tool 300 at the predetermined intervals by the plurality of support rods 315 supported by the base 311. The plurality of substrates S supported by the support rods 315 is partitioned by the partition plates 314 having the disk shape fixed (supported) to the column 313 supported by the partition plate support 310 at the predetermined intervals. Here, the partition plate 314 is disposed above or below the substrate S, or both.

The predetermined interval between the plurality of substrates S placed on the substrate support tool 300 is the same as the vertical interval between the partition plates 314 fixed to the partition plate support 310. The diameter of the partition plate 314 is larger than the diameter of the substrate S.

The substrate support tool 300 supports a plurality of, for example, five substrates S in multiple stages in the vertical direction with the plurality of support rods 315. The base 311 and the plurality of support rods 315 are formed of a material such as quartz or SiC, for example. Note that, here, an example in which five substrates S are supported by the substrate support tool 300 is illustrated, but the present embodiment is not limited thereto. For example, the substrate support tool 300 may be capable of supporting 5 to 50 substrates S. The partition plate 314 of the partition plate support 310 is also referred to as a separator.

That is, the substrate support tool 300 is configured to stack a plurality of substrates S. As will be described in detail later, the substrate support tool 300 is configured such that the plurality of substrates S held by the substrate support tool 300 is divided into at least two regions (for example, an upper region and a lower region) in the stacking direction. Then, the first distributor 2221 and the second distributor 2222 constituting the distributor 222 are disposed so as to correspond to the respective divided regions.

The partition plate support 310 and the substrate support tool 300 are driven by the up-down direction drive mechanism 400 in the up-down direction between the reaction tube 210 and the transfer chamber 217 and in the rotational direction around the center of the substrate S supported by the substrate support tool 300.

The up-down direction drive mechanism 400 constituting the first driver includes an upward/downward drive motor 410 and a rotation drive motor 430 serving as drive sources, and a boat elevator 420 including a linear actuator serving as a substrate support tool lift mechanism that drives the substrate support tool 300 in the up-down direction.

### Gas Supply System

Next, details of a gas supply system will be described.

The gas supply system includes a first gas supply system that performs gas supply through the gas supply pipe 251 and a second gas supply system that performs gas supply through the gas supply pipe 261.

### First Gas Supply System

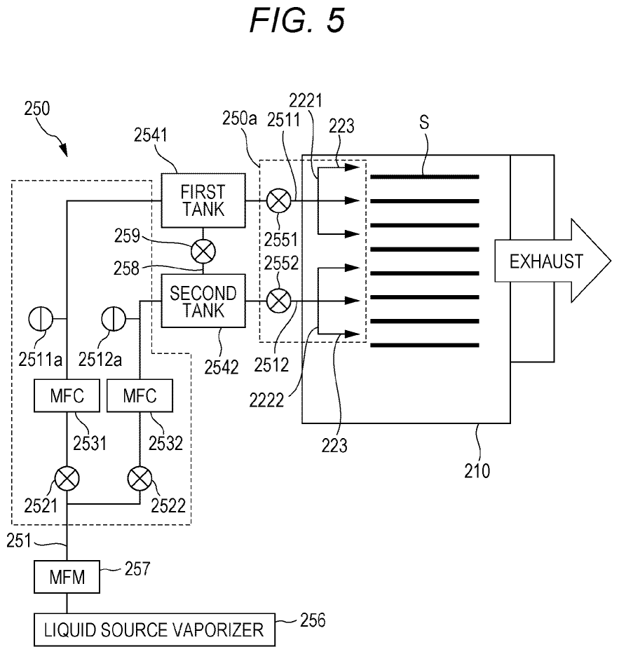

FIG. 5 is an explanatory diagram illustrating an example of the first gas supply system.

As described above, the distributor 222 includes the first distributor 2221 and the second distributor 2222. Correspondingly, the gas supply pipe 251 includes a first gas supply pipe 2511 communicating with the first distributor 2221 and a second gas supply pipe 2512 communicating with the second distributor 2222.

The first gas supply pipe 2511 is provided with a third valve 2521 that is an on-off valve, a mass flow controller (MFC) 2531 that is a flow rate control device (flow rate controller), a first flash tank (Hereinafter, the first flash tank is also referred to as a “first tank”.) 2541 that is a gas accumulation container, and a second valve 2551 in this order from the upstream side. A digital gauge 2511a may be coupled to the first gas supply pipe 2511.

Similarly, in the second gas supply pipe 2512, a third valve 2522, an MFC 2532, a second flash tank (Hereinafter, the second flash tank is also referred to as a “second tank”.) 2542, and a second valve 2552 are provided in this order from the upstream side. A digital gauge 2512a may be coupled to the second gas supply pipe 2512.

The first tank 2541 and the second tank 2542 are coupled to each other by pipe (piping) 258. The pipe 258 is provided with a first valve 259 that is an on-off valve.

On the upstream side of the third valves 2521 and 2522, the first gas supply pipe 2511 and the second gas supply pipe 2512 merge and are coupled to one gas supply pipe 251. The gas supply pipe 251 is provided with a liquid source vaporizer 256 and a mass flow meter (MFM) 257 that is a mass flow rate meter in this order from the upstream side.

The liquid source vaporizer 256 vaporizes a source supplied as a liquid to generate a source gas. Hereinafter, the liquid source vaporizer may be simply referred to as a “vaporizer”.

The source gas generated by the vaporizer 256 is the first gas (It is also referred to as a “first element-containing gas”.) containing a first element, and is one of processing gases. Specifically, the source gas is, for example, a gas in which at least two atoms of silicon (Si) are bonded and containing Si and chlorine (Cl), and is a gas containing a Si—Si bond, such as a hexachlorodisilane (Si₂Cl₆, abbreviation: HCDS) gas.

The first gas supply system (It is also referred to as a “source gas supply system”.) 250 mainly includes the gas supply pipe 251, the first gas supply pipe 2511, the second gas supply pipe 2512, the first tank 2541, the second tank 2542, the pipe 258, the first valve 259, the second valves 2551 and 2552, and the third valves 2521 and 2522. The liquid source vaporizer 256 may be added to the first gas supply system 250. According to the source gas supply system 250 having such a configuration, by using the first tank 2541 and the second tank 2542, as will be described in detail later, it is possible to supply the source gas to the reaction tube (process chamber) 210 at a large flow rate in a short time.

That is, the source gas supply system 250 includes a gas supplier 250a that supplies the source gas from the first tank 2541 and the second tank 2542 into the process chamber 210.

The gas supplier 250a roughly includes a portion corresponding to the first tank 2541 and a portion corresponding to the second tank 2542. This means that the same number of gas suppliers 250a as the first tanks 2541 and the second tanks 2542 are provided.

Specifically, the corresponding portion to the first tank 2541 in the gas supplier 250a mainly includes the first gas supply pipe 2511 extending from the first tank 2541 and the second valve 2551 disposed in the first gas supply pipe 2511. The corresponding portion may include the first distributor 2221 communicating with the first gas supply pipe 2511 and the nozzle 223 provided in the first distributor 2221.

The corresponding portion to the second tank 2542 in the gas supplier 250a mainly includes the second gas supply pipe 2512 extending from the second tank 2542 and the second valve 2552 disposed in the second gas supply pipe 2512. The corresponding portion may include the second distributor 2222 communicating with the second gas supply pipe 2512 and the nozzle 223 provided in the second distributor 2222.

As described above, in the gas supplier 250a, the second valves 2551 and 2552 are provided between the first tank 2541 and the second tank 2542 and the process chamber 210, respectively.

In addition, since the gas supplier 250a corresponds to each of the first distributor 2221 and the second distributor 2222, the source gas is supplied to each of at least two divided regions in the substrate stacking direction in the substrate support tool 300.

Furthermore, the gas supplier 250a supplies the source gas through each nozzle 223 provided in the distributor 222, and thus supplies the source gas to each of the plurality of substrates S held by the substrate support tool 300.

In the source gas supply system 250, an inert gas supply pipe (not illustrated) to which an inert gas, for example, nitrogen (N₂) gas is supplied from an inert gas source (not illustrated) may be coupled to the first gas supply pipe 2511 and the second gas supply pipe 2512. The inert gas supply pipe may be coupled to the gas supply pipe 251.

### Second Gas Supply System

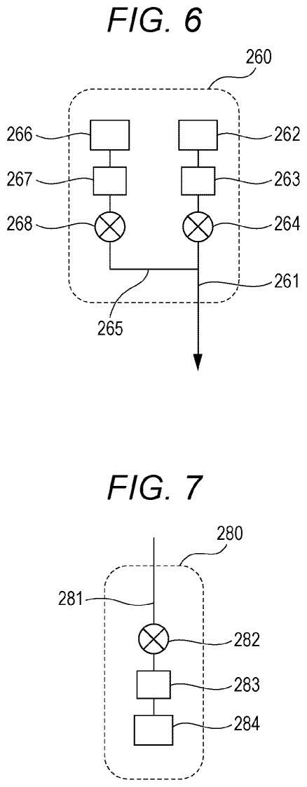

FIG. 6 is an explanatory diagram illustrating the second gas supply system.

As in the illustrated example, the gas supply pipe 261 is provided with a second gas source 262, an MFC 263, and a valve 264 in this order from the upstream direction. The gas supply pipe 261 is coupled to the introduction pipe 224b of the distributor 224.

The second gas source 262 is a second gas (which is also referred to as a “second element-containing gas” hereinafter) source containing a second element. The second element-containing gas is one of the processing gases. The second element-containing gas may be considered as a reactant gas or a modifying gas.

Here, the second element-containing gas contains the second element different from the first element. The second element is, for example, any one of oxygen (O), nitrogen (N), and carbon (C). In the present aspect, the second element-containing gas is, for example, a nitrogen-containing gas. Specifically, the second element-containing gas is a hydrogen nitride-based gas containing an N—H bond, such as ammonia (NH₃), diazene (N₂H₂) gas, hydrazine (N₂H₄) gas, or N₃H₈ gas.

The second gas supply system (also referred to as a “reactant gas supply system) 260 mainly includes the gas supply pipe 261, the MFC 263, and the valve 264.

A gas supply pipe 265 is coupled to the downstream side of the valve 264 of the supply pipe 261. In the gas supply pipe 265, an inert gas source 266, an MFC 267, and a valve 268 are provided in this order from the upstream direction. An inert gas, for example, N₂ gas is supplied from the inert gas source 266.

A second inert gas supply system mainly includes the gas supply pipe 265, the MFC 267, and the valve 268. The inert gas supplied from the inert gas source 266 acts as a purge gas for purging the gas remaining in the reaction tube 210 in a substrate processing step. The second inert gas supply system may be added to the second gas supply system 260.

### Exhaust System

Next, a gas exhaust system will be described.

FIG. 7 is an explanatory diagram illustrating the gas exhaust system.

As in the illustrated example, an exhaust system 280 that exhausts the atmosphere of the reaction tube 210 includes an exhaust pipe 281 communicating with the reaction tube 210, and is coupled to the housing 241 through the gas exhaust pipe connector 242.

To the exhaust pipe 281, a vacuum pump 284 as a vacuum exhaust device is coupled through a valve 282 as an on-off valve and an auto pressure controller (APC) valve 283 as a pressure regulating device (pressure regulator), which is configured to be able to perform vacuum exhaust such that a pressure in the reaction tube 210 is a predetermined pressure (degree of vacuum). The exhaust system 280 is also referred to as a process chamber exhaust system.

### Controller

Next, a controller will be described.

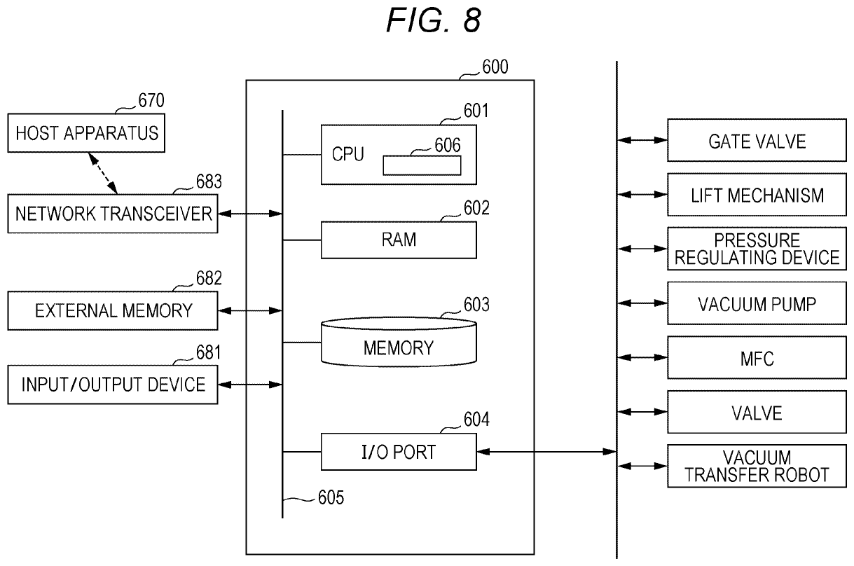

FIG. 8 is an explanatory diagram explaining the controller of the substrate processing apparatus.

The substrate processing apparatus 100 includes a controller 600 that controls operation of each constituent of the substrate processing apparatus 100.

The controller 600 serving as a controller is configured as a computer including a central processing unit (CPU) 601, a random access memory (RAM) 602, a memory 603 serving as a memory, and an I/O port 604. The RAM 602, the memory 603, and the I/O port 604 are capable of exchanging data with the CPU 601 via an internal bus 605. Transmission/reception of data in the substrate processing apparatus 100 is performed on the basis of an instruction from a transmission/reception instructor 606 that is one function of the CPU 601.

The controller 600 is provided with a network transceiver 683 connected to a host apparatus 670 via a network. The network transceiver 683 can receive, for example, information regarding the processing history and the processing schedule of the substrate S stored in a pod 111 from the host apparatus.

The memory 603 includes, for example, a flash memory, a hard disk drive (HDD), or the like. The memory 603 readably stores therein a control program for controlling the operation of the substrate processing apparatus, a process recipe describing procedures and conditions of the substrate processing, and the like.

The process recipe functions as a program for causing the controller 600 to perform each procedure in the substrate processing step to be described later to obtain a predetermined result. Hereinafter, the process recipe, the control program, and the like will also be collectively and simply referred to as a program. The term “program” in the present specification may include only the process recipe alone, only the control program alone, or both of them. The RAM 602 is configured as a memory area (work area) in which programs, data, and the like read by the CPU 601 are temporarily stored.

The I/O port 604 is connected to each component of the substrate processing apparatus 100. The CPU 601 reads the control program from the memory 603 to execute it, and reads the process recipe from the memory 603 in response to an input of an operation command from an input/output device 681 or the like. Then, the CPU 601 is configured to be able to control the substrate processing apparatus 100 in accordance with the content of the read process recipe.

The CPU 601 includes the transmission/reception instructor 606. For example, by installing the program into a computer with use of an external memory (e.g., magnetic disk such as a hard disk, optical disk such as a digital versatile disc (DVD), magneto-optical disk such as a magneto-optical disc (MO), or semiconductor memory such as a universal serial bus (USB) memory) 682 storing the program described above, it is possible to configure the controller 600 according to the present aspect. However, the means for supplying the program to the computer is not limited to the case of supplying the program through the external memory 682. For example, the program may be supplied using a communication means such as the Internet or a dedicated line, instead of through the external memory 682. Note that the memory 603 and the external memory 682 are configured as a computer-readable recording medium. Hereinafter, these will also be collectively and simply referred to as a recording medium. The term “recording medium” in the present specification may include only the memory 603 alone, only the external memory 682 alone, or both of them.

### (2) Procedure of Substrate Processing Step

Next, a step of forming a thin film on the substrate S using the substrate processing apparatus 100 having the configuration described above will be described as one step of a semiconductor manufacturing step. In the following descriptions, the operation of each constituent included in the substrate processing apparatus is controlled by the controller 600.

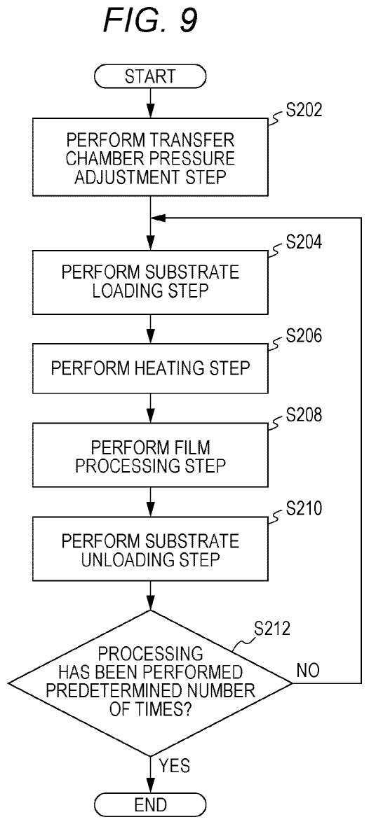

Here, film forming processing for forming a film on the substrate S by alternately supplying the first gas and the second gas will be described with reference to FIG. 9. FIG. 9 is a flow diagram explaining a substrate processing flow.

### Transfer Chamber Pressure Adjustment Step: S202

First, a transfer chamber pressure adjustment step (S202) will be described. Here, the pressure in the transfer chamber 217 is assumed to be the same level as that in a vacuum transfer chamber 140. Specifically, an exhaust system (not illustrated) coupled to the transfer chamber 217 is operated to exhaust the atmosphere in the transfer chamber 217 so that the atmosphere in the transfer chamber 217 reaches a vacuum level.

The heater 228 may be operated in parallel with this step. Specifically, each of the heater 228a and the heater 228b may be operated. In a case where the heater 228 is operated, it is operated at least during a film processing step 208 to be described later.

### Substrate Loading Step: S204

Next, a substrate loading step (S204) will be described.

When the transfer chamber 217 reaches the vacuum level, transfer of the substrates S is started. When the substrates S arrive at the vacuum transfer chamber 140, a gate valve (not illustrated) adjacent to the substrate loading port 149 is released, and the substrates S are loaded into the transfer chamber 217 from an adjacent vacuum transfer chamber (not illustrated).

At this time, the substrate support tool 300 stands by in the transfer chamber 217, and the substrates S are transferred to the substrate support tool 300. When a predetermined number of substrates S are transferred to the substrate support tool 300, the vacuum transfer robot is retracted to a housing 141, and the substrate support tool 300 is raised to move the substrates S into the reaction tube 210.

In the movement to the reaction tube 210, the surface of the substrate S is positioned to be aligned with the height of the division plate 226 and the division plate 232.

### Heating Step: S206

A heating step (S206) will be described. When the substrates S are loaded into the reaction tube 210, the inside of the reaction tube 210 is controlled to have a predetermined pressure, and the heater 211 is controlled such that the surface temperature of the substrates S reaches a predetermined temperature. The heat is added to increase the temperature to a high temperature zone to be described later, which is, for example, 400° C. or higher and 800° C. or lower. The temperature is preferably 500° C. or higher and 700° C. or lower. The pressure may be, for example, 50 to 5,000 Pa. In a case where the upstream side heater 228 is operated at this time, control is performed such that the gas passing through the distributor 222 is heated to a temperature in a low-decomposition temperature zone or a non-decomposition zone to be described later and at which re-liquefaction does not occur. For example, the heat is added such that the temperature of the gas reaches approximately 300° C.

### Film Processing Step: S208

A film processing step (S208) will be described. After the heating step (S206), the film processing step (S208) is performed. In the film processing step (S208), the source gas (first gas) supply system 250 is controlled according to the process recipe to supply the first gas into the reaction tube 210, and the exhaust system 280 is controlled to exhaust the processing gas from the reaction tube 210, whereby the film processing is performed. Here, the reactant gas (second gas) supply system 260 may be controlled to cause the second gas to be in a processing space simultaneously with the first gas to perform CVD processing, or the first gas and the second gas may be alternately supplied into the reaction tube 210 to perform alternate supply processing. In a case where the second gas is made into a plasma state and processing is performed, the second gas may be made into the plasma state using a plasma generator (not illustrated).

The following method is conceivable as the alternate supply processing, which is a specific example of the film processing method. For example, the first gas is supplied into the reaction tube 210 in a first step, the second gas is supplied into the reaction tube 210 in a second step, an inert gas is supplied into the reaction tube 210 and the atmosphere in the reaction tube 210 is exhausted as a purge step between the first step and the second step, and the alternate supply processing is performed in which a combination of the first step, the purge step, and the second step is performed a plurality of times, whereby a desired film is formed.

A gas flow of the supplied gas is formed in the upstream side gas guide 214, spaces above the substrates S, and the downstream side gas guide 215. At this time, since the gas is supplied to the individual substrates S in a state where there is no pressure loss on the substrates S, uniform processing can be performed among the substrates S.

### Substrate Unloading Step: S210

A substrate unloading step (S210) will be described. In the substrate unloading step (S210), the processed substrates S are unloaded outward from the transfer chamber 217 in a reverse procedure to the substrate loading step S204 described above.

### Determination: S212

A determination (S212) will be described. In the determination, it is determined whether or not the substrates have been processed a predetermined number of times. When it is determined that the substrates have not been processed the predetermined number of times, the processing returns to the loading step S204, and the next substrates S are processed. When it is determined that the substrates have been processed the predetermined number of times, the processing is terminated.

While the formation of the horizontal gas flow has been described above, it is sufficient if the mainstream of the gas is formed in the horizontal direction as a whole, and the gas flow may be diffused in the vertical direction as long as the uniform processing of the plurality of substrates is not affected.

In addition, it is needless to say that the expressions of the same level, equivalent, equal, and the like in the descriptions above include the meaning of substantially the same.

### (3) Control Processing at Time of Gas Supply

Next, a description will be given of control processing when the source gas is supplied as the first gas to the reaction tube (process chamber) 210 in the film processing step (S208) of the substrate processing step described above.

When the source gas is supplied, first, in FIG. 5, the second valve 2551 is closed while the third valve 2521 in the first gas supply pipe 2511 is opened, whereby gas charge is performed of the source gas into the first tank 2541. Similarly, the second valve 2552 is closed while the third valve 2522 in the second gas supply pipe 2512 is opened, whereby gas charge is performed of the source gas into the second tank 2542.

The gas charge into the first tank 2541 and the second tank 2542 is performed until an amount of gas charge reaches a range of 30 kPa to 50 kPa in a case where each tank capacity is 1000 cc, for example. Note that the expression of a numerical range such as “30 kPa to 50 kPa” in the present specification means that the lower limit and the upper limit are included in the range. Thus, for example, “30 kPa to 50 kPa” means “30 kPa or higher and 50 kPa or lower”. The same applies to other numerical ranges.

Then, after the gas charge into the first tank 2541 and the second tank 2542, the second valve 2551 is opened while the third valve 2521 in the first gas supply pipe 2511 is s closed. Furthermore, the second valve 2552 is opened while the third valve 2522 in the second gas supply pipe 2512 is closed. As a result, the source gas accumulated in the first tank 2541 and the second tank 2542 is supplied to the process chamber 210 at a large flow rate in a short time.

In a case where gas supply is performed using a plurality of the first tanks 2541 and the second tanks 2542, the following problems may occur. For example, in gas flow paths from the liquid source vaporizer 256 to the first tank 2541 and the second tank 2542, if there is a difference in conductance between the gas flow paths, amounts of gas charge into the first tank 2541 and the second tank 2542 may be non-uniform. When the respective amounts of gas charge are non-uniform, the influence reaches the gas supply to the process chamber 210, and as a result, there is a possibility that a difference occurs in the film formation situation of the substrate S between a corresponding region of the first distributor 2221 and a corresponding region of the second distributor 2222.

In this regard, in the substrate processing apparatus 100 according to the present aspect, the first tank 2541 and the second tank 2542 are coupled to each other by the pipe 258, and the first valve 259 is provided in the pipe 258. When gas supply is performed using the first tank 2541 and the second tank 2542, the controller 600 performs control processing described below.

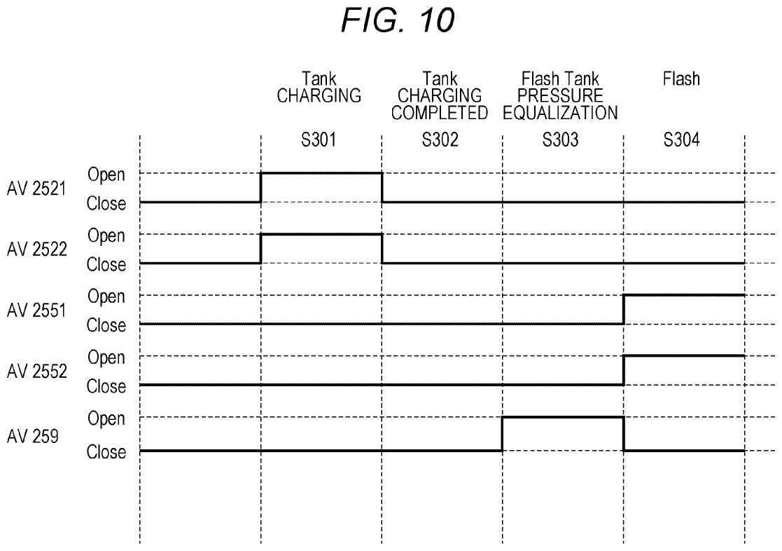

FIG. 10 is a chart diagram explaining control processing at the time of gas supply.

In the drawing, the first valve 259 is simply referred to as “AV (air valve) 259”. The same applies to the second valves 2551 and 2552 and the third valves 2521 and 2522.

As illustrated in FIG. 10, when the source gas is supplied, first, the controller 600 opens the AVs 2521 and 2522, and closes the other AVs 2551, 2552, and 259. As a result, gas charge is performed of the source gas into the first tank 2541 and the second tank 2542 (S301). Then, when the amounts of gas charge into the first tank 2541 and the second tank 2542 reach a predetermined range, the AVs 2521 and 2522 are closed, and the gas charge into the first tank 2541 and the second tank 2542 is completed (S302).

Thereafter, the controller 600 opens the AV 259 at a predetermined timing before starting gas supply to the process chamber 210 (for example, a timing immediately before the start). The other AVs 2521, 2522, 2551, and 2552 are kept closed. As a result, the first tank 2541 and the second tank 2542 communicate with each other through the pipe 258, and the inside of the first tank 2541 and the inside of the second tank 2542 are equalized in pressure (S303). That is, the amount of gas charge in the first tank 2541 and the amount of gas charge in the second tank 2542 become uniform.

Then, after a predetermined time (for example, a time necessary and sufficient for pressure equalization) has elapsed since the AV 259 was opened, the controller 600 closes the AV 259. Furthermore, the controller 600 opens the AVs 2551 and 2552 in accordance with the closing of the AV 259. However, the AVs 2521 and 2522 are kept closed. As a result, gas supply is performed from each of the first tank 2541 and the second tank 2542 into the process chamber 210 (S304). That is, the controller 600 opens the AV 259 to equalize the pressures of the first tank 2541 and the second tank 2542, and then supplies the source gas to the process chamber 210.

Specifically, the source gas in the first tank 2541 is supplied to the corresponding region in the process chamber 210 through the first gas supply pipe 2511, the first distributor 2221, and the nozzle 223. In addition, the source gas in the second tank 2542 is supplied to the corresponding region in the process chamber 210 through the second gas supply pipe 2512, the second distributor 2222, and the nozzle 223. In that case, the source gas is simultaneously supplied from the first tank 2541 and the second tank 2542 to the process chamber 210 by matching the timings to open the AVs 2551 and 2552.

At this time, the inside of the first tank 2541 and the inside of the second tank 2542 are equalized in pressure, and gas supply from the first tank 2541 and the second tank 2542 is simultaneously performed, so that the gas supply into the process chamber 210 does not become non-uniform in the corresponding regions. Thus, even in a case where the corresponding region of the first distributor 2221 and the corresponding region of the second distributor 2222 are different from each other, no difference occurs in the film formation situation of the substrate S between the respective corresponding regions. Note that “simultaneous” may be any degree as long as it is achieved that the gas supply does not become non-uniform between the corresponding regions, and may not be completely simultaneous.

### (4) Effects According to Present Embodiments

According to the present embodiments, one or more effects to be described below are exhibited.
(a) In the present embodiments, since the first valve 259 is provided in the pipe 258 between the first tank 2541 and the second tank 2542, the inside of the first tank 2541 and the inside of the second tank 2542 can be equalized in pressure prior to the supply of the source gas into the process chamber 210. Therefore, for example, even in a case where there is a difference in conductance between the gas flow paths to the first tank 2541 and the second tank 2542, the amounts of gas charge in the respective tanks do not become non-uniform. As described above, when the amounts of gas charge become uniform between the first distributor 2221 and the second distributor 2222, no difference occurs in the film formation situation of the substrate S between the corresponding region of the first distributor and the corresponding region of the second distributor, and it is possible to uniformly perform the processing on the plurality of substrates S.
(b) In the present embodiments, in supply of the source gas into the process chamber 210, the inside of the first tank 2541 and the inside of the second tank 2542 are equalized in pressure, and then the gas supply is simultaneously performed from each tank. Therefore, it is possible to reliably uniformize the processing on the plurality of substrates S.

### (5) Modified Examples, etc.

While the embodiments of the present disclosure have been specifically described above, the present disclosure is not limited to the embodiments described above, and various modifications can be made without departing from the gist of the present disclosure.

In the above-described embodiments, as an example, a case has been described where the first gas supply system (source gas supply system) 250 includes one vaporizer 256, but the present disclosure is not limited to the example.

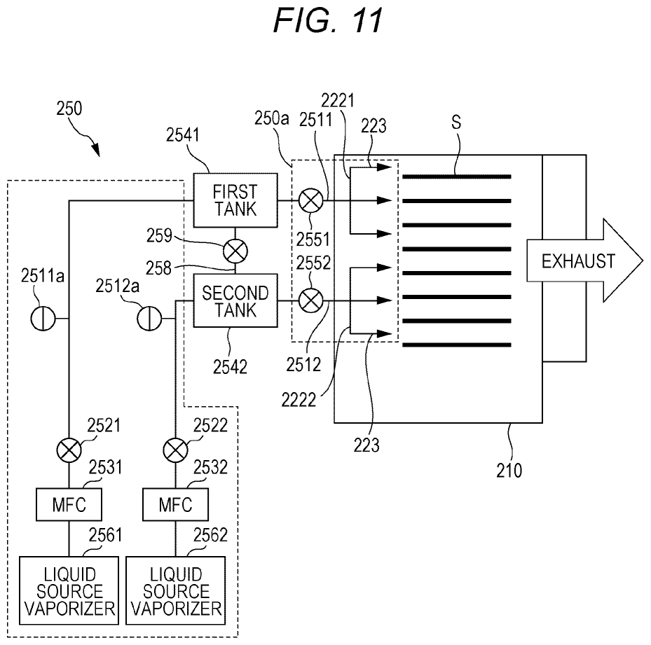

FIG. 11 is an explanatory diagram illustrating another example of the first gas supply system.

In the first gas supply system of the illustrated example, vaporizers 2561 and 2562 are individually provided for the first gas supply pipe 2511 and the second gas supply pipe 2512, respectively. That is, the same number of vaporizers 2561 and 2562 as the first tank 2541 and the second tank 2542 are provided.

Even in such a configuration, if there is a difference in conductance between gas flow paths from the vaporizers 2561 and 2562 to the first tank 2541 and the second tank 2542, respective amounts of gas charge may be non-uniform. However, when the first valve 259 is provided in the pipe 258 between the first tank 2541 and the second tank 2542 as in the illustrated example, the amounts of gas charge in the respective tanks can be uniformed, and as a result, it is possible to uniformly perform processing on the plurality of substrates S.

As described above, in the present disclosure, it is sufficient that at least one vaporizer is provided.

In addition, in the above-described embodiments, as an example, a case has been described where the plurality of substrates S is divided into the upper region and the lower region, and gas supply is performed from the first tank 2541 and the second tank 2542 to each region, but the present disclosure is not limited to the example.

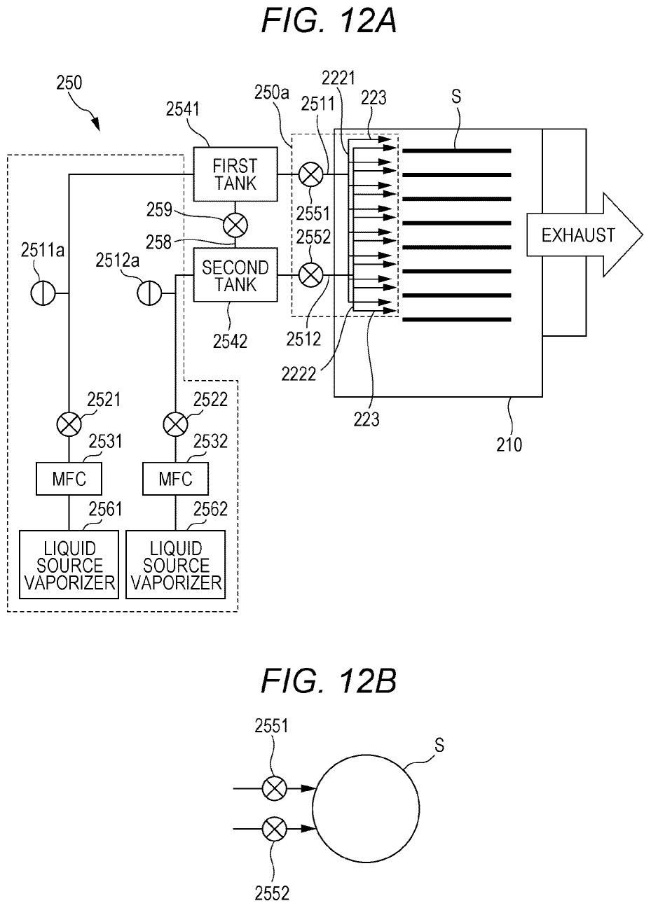

FIGS. 12A and 12B are explanatory diagrams illustrating still another example of the first gas supply system, in which FIG. 12A is a diagram illustrating an overall schematic configuration, and FIG. 12B is a diagram of a substrate periphery viewed from above.

In the first gas supply system in the illustrated example, as illustrated in FIG. 12A, the nozzles 223 provided in the first distributor 2221 and the nozzles 223 provided in the second distributor 2222 are disposed so as to correspond to the respective plurality of substrates S. As illustrated in FIG. 12B, the nozzles 223 of the first distributor 2221, which are coupled to the second valve 2551, and the nozzles 223 of the second distributor 2222, which are coupled to the second valve 2552, are disposed side by side in the horizontal direction with respect to the substrates S.

Even in such a configuration, by making the amounts of gas charge of the first tank 2541 and the second tank 2542 uniform, it is possible to uniformly perform the processing on each of the plurality of substrates S.

That is, an aspect of region division in the stacking direction of the plurality of substrates S is not particularly limited, and can be appropriately set.

In addition, in the above-described embodiments, as an example, a case has been described where the plurality of substrates S is divided into two regions in the stacking direction, and the first tank 2541 and the second tank 2542 are provided corresponding to the respective divided regions, but the present disclosure is not limited to the example.

For example, the plurality of substrates S may be divided into three or more regions in the stacking direction. In that case, the distributor 222, the tanks 2541 and 2542, and the first gas supply system (source gas supply system) 250 are also provided corresponding to the respective divided regions.

That is, in the present disclosure, it is sufficient that the plurality of substrates S is divided into at least two regions in the stacking direction, and at least two tanks for accumulating the source gas are provided correspondingly.

In addition, for example, in each embodiment described above, as an example, a case has been described where a film is formed on the substrate S using the first gas and the second gas in the film forming processing performed by the substrate processing apparatus, but the present aspect is not limited to this. That is, another type of thin film may be formed using another type of gas as the processing gas used for the film forming processing. Furthermore, even in a case where three or more types of processing gases are used, the present aspect can be applied as long as these are alternately supplied to perform the film forming processing. Specifically, the first element may be various elements, for example, titanium (Ti), silicon (Si), zirconium (Zr), and hafnium (Hf). The second element may be, for example, nitrogen (N), oxygen (O), or the like. The first element is more desirably Si as described above.

While the HCDS gas has been exemplified as the first gas here, the first gas is not limited thereto as long as it contains silicon and has a Si—Si bond, and for example, tetrachlorodimethyldisilane ((CH₃)₂Si₂Cl₄, abbreviation: TCDMDS) or dichlorotetramethyldisilane ((CH₃)₄Si₂Cl₂, abbreviation: DCTMDS) may be used. TCDMDS has a Si—Si bond, and further contains a chloro group and an alkylene group. DCTMDS has a Si—Si bond, and further contains a chloro group and an alkylene group.

For example, in each embodiment described above, as an example, film forming processing has been described as processing performed by the substrate processing apparatus, but the present aspect is not limited to this. That is, the present aspect can be applied to film forming processing other than the thin film exemplified in each embodiment, in addition to the film-forming processing exemplified in each embodiment. Part of the constituents in an embodiment can be replaced with a constituent in another embodiment. A constituent in an embodiment can be added to the constituents in another embodiment. Part of the constituents in each embodiment can be given another constituent, can be deleted, or can be replaced with another constituent.

In addition, for example, in the above-described aspect, an example has been described in which a film is formed by using a batch-type substrate processing apparatus that processes a plurality of substrates at a time. The present disclosure is not limited to the above-described aspect, and can be suitably applied to a case of forming a film by using a single wafer type substrate processing apparatus that processes one or more substrates at a time, for example. In the above-described aspect, an example has been described in which a film is formed by using a substrate processing apparatus including a hot wall-type processing furnace. The present disclosure is not limited to the above-described aspect, and can be suitably applied to a case of forming a film by using a substrate processing apparatus including a cold wall-type processing furnace.

Even in cases where such substrate processing apparatuses are used, each of types of processing can be performed in accordance with processing procedures and processing conditions similar to those in the above-described aspect and modified examples, so that effects similar to those in the above-described aspect and modified examples can be obtained.

Also in the present modified examples as described above, the effects similar to those in the above-described aspect can be obtained. The above-described aspect and the modified examples can be appropriately combined for use. The processing procedures and processing conditions at that time can be similar to the processing procedures and processing conditions in the above-described aspect and modified examples, for example.

According to one aspect of the present disclosure, a technique can be provided that makes it possible to uniformly perform processing on a plurality of substrates.

What is claimed is:

1. A substrate processing apparatus comprising:
a process chamber configured to process a substrate;
at least one vaporizer that vaporizes a source supplied as a liquid to generate a source gas;
at least two tanks that accumulates the source gas extracted from the vaporizer;
a pipe coupling the at least two tanks to each other;
a first valve provided in the pipe; and
a gas supplier that supplies the source gas into the process chamber from the at least two tanks.

2. The substrate processing apparatus according to claim 1, wherein the first valve is opened to equalize pressures of the at least two tanks, and then the source gas is supplied to the process chamber.

3. The substrate processing apparatus according to claim 2, wherein the source gas is supplied to the process chamber simultaneously from the at least two tanks.

4. The substrate processing apparatus according to claim 3, wherein an identical number of the gas suppliers as the tanks are provided.

5. The substrate processing apparatus according to claim 4, wherein second valves are provided respectively in the gas suppliers between the tanks and the process chamber.

6. The substrate processing apparatus according to claim 5, wherein the second valves are simultaneously opened when the source gas is supplied to the process chamber.

7. The substrate processing apparatus according to claim 1, wherein the pipe is provided between the at least two tanks.

8. The substrate processing apparatus according to claim 7, wherein the first valve is opened and the at least two tanks communicate with each other through the pipe, and the at least two tanks are equalized in pressure.

9. The substrate processing apparatus according to claim 8, wherein amounts of gas charged in the at least two tanks are uniform.

10. The substrate processing apparatus according to claim 2, further comprising a substrate holder that stacks a plurality of the substrates.

11. The substrate processing apparatus according to claim 10, wherein
the plurality of the substrates held by the substrate holder is divided into at least two regions in a stacking direction, and
the gas supplier supplies the source gas to the at least two regions.

12. The substrate processing apparatus according to claim 11, wherein there are an identical number of gas suppliers as tanks.

13. The substrate processing apparatus according to claim 12, wherein there are an identical number of vaporizers as tanks.

14. The substrate processing apparatus according to claim 10, wherein the gas supplier supplies the source gas to each of the plurality of substrates.

15. The substrate processing apparatus according to claim 14, wherein there are an identical number of gas suppliers as tanks.

16. The substrate processing apparatus according to claim 15, wherein there are an identical number of vaporizers as tanks.

17. A method of processing a substrate, comprising:
loading a substrate into a process chamber of a substrate processing apparatus including: the process chamber being configured to process the substrate; at least one vaporizer that vaporizes a source supplied as a liquid to generate a source gas; at least two tanks that accumulate the source gas extracted from the vaporizer; pipe coupling the at least two tanks to each other; a first valve provided in the pipe; and a gas supplier that supplies the source gas into the process chamber from the at least two tanks; and
supplying the source gas to the process chamber.

18. A method of manufacturing a semiconductor device, using the method of processing a substrate according to claim 17.

19. A non-transitory computer-readable recording medium recording a program for causing a substrate processing apparatus to execute procedures by a computer, the procedures including:
a procedure of loading a substrate into a process chamber of the substrate processing apparatus including: the process chamber being configured to process the substrate; at least one vaporizer that vaporizes a source supplied as a liquid to generate a source gas; at least two tanks that accumulates the source gas extracted from the vaporizer; pipe coupling the at least two tanks to each other; a first valve provided in the pipe; and a gas supplier that supplies the source gas into the process chamber from the at least two tanks; and
a procedure of supplying the source gas to the process chamber.
